(19) United States
(12) Patent Application Publication
(10) Pub. No.: US 2022/0033976 A1
(43) Pub. Date: Feb. 3, 2022

(54) METHOD FOR INHIBITING GENERATION OF RUTHENIUM-CONTAINING GAS FROM RUTHENIUM-CONTAINING LIQUID

(71) Applicant: TOKUYAMA CORPORATION, Yamaguchi (JP)

(72) Inventors: Tomoaki SATO, Yamaguchi (JP); Fuyuki SATO, Yamaguchi (JP); Takayuki NEGISHI, Yamaguchi (JP)

(73) Assignee: TOKUYAMA CORPORATION, Yamaguchi (JP)

(21) Appl. No.: 17/386,135

(22) Filed: Jul. 27, 2021

(30) Foreign Application Priority Data
Jul. 28, 2020 (JP) 2020-126925

(51) Int. Cl. C23F 1/44; H01L 21/306; C23F 1/38

(52) U.S. Cl. CPC C23F 1/44; C23F 1/38; H01L 21/30604

(57) ABSTRACT

The present invention provides a method for inhibiting a RuO₄ gas generated from a ruthenium-containing liquid in the production process of a semiconductor element. The present invention provides a method for inhibiting a Ru₄ gas generated from a ruthenium-containing liquid by adding an inhibitor for inhibiting the generation of a RuO₄ gas, to a ruthenium-containing liquid. The present invention also provides an inhibitor for inhibiting the generation of a RuO₄ gas, including at least one of a reducing agent and a basic compound.

### TECHNICAL FIELD

The present invention relates to a novel method for inhibiting the generation of a RuO₄ gas from a ruthenium-containing liquid, in which the gas is generated in the production process of a semiconductor element.

### BACKGROUND ART

In recent years, the miniaturization of design rules for semiconductor elements have been in progress, and there has been a tendency for an increase in wiring resistance. As a result of the increased wiring resistance, high-speed operations of semiconductor elements tend to be significantly hindered, and countermeasures therefor have been needed. Therefore, wiring materials in which electromigration resistance is high and the resistance value is reduced as compared with those of conventional wiring materials are needed.

Ruthenium is drawing attention as a wiring material for use in a semiconductor element with a design rule of 10 nm or less, in particular, because ruthenium has a higher electromigration resistance, and is capable of reducing the wiring resistance value, as compared to aluminum and copper which are conventional wiring materials. In addition, since ruthenium is capable of preventing the electromigration even in cases where copper is used as a wiring material, the use of ruthenium has been investigated not only as a wiring material, but also as a barrier metal for a copper wiring.

Even in cases where ruthenium is selected as a wiring material in the step of forming the wiring of a semiconductor element, the wiring is formed by dry or wet etching, in the same manner as in the case of using a conventional wiring material. However, since it is difficult to etch ruthenium by dry etching with an etching gas or etching by CMP polishing, and to remove ruthenium, a more precise etching is desired. Specifically, wet etching is drawing attention.

In cases where ruthenium is etched by wet etching, ruthenium is dissolved in the form of, for example, RuO₂, RuO₄⁻, or RuO₄²⁻ in a liquid. RuO₂, RuO₄⁻, or RuO₄²⁻ is converted into RuO₄ in such a liquid and RuO₄ is partially gasified and released into a gas phase. RuO₄ is strongly oxidative and thus is harmful to human body. It is very important in view of such a background to inhibit the generation of a RuO₄ gas from a ruthenium-containing liquid.

Patent Document 1 proposes a method involving heat-treating RuO₄ volatilized from a ruthenium-containing liquid, at 200° C., to thereby recover it as RuO₂.

Patent Document 2 proposes a method involving adding a metal ferrocyanide compound to a ruthenium-containing liquid to thereby enable a ruthenium-containing compound to be removed by adsorption.

### RELATED ART

### Patent Documents

Patent Document 1: Japanese Patent Application Publication No. 2014-48084

Patent Document 2: International Publication No. WO 2013/121867

### SUMMARY OF THE INVENTION

### Problems to be Solved by the Invention

However, according to the investigation by the present inventors, it has been found out that there is room for improvement for the method for inhibiting a RuO₄ gas disclosed in each of Patent Documents 1 and 2, in the following points.

The method disclosed in Patent Document 1 involves volatilizing and separating ruthenium in a liquid, in the form of RuO₄, and then performing a heat treatment at 200° C., and thus steps, for example, such volatilization, separation, and heating are complicated. Any apparatus for carrying out such each step is also needed, and thus the treatment cost is increased.

The method disclosed in Patent Document 2, while is a simple method involving adding a metal ferrocyanide compound to a ruthenium-containing liquid, exhibits a rate of recovery of a ruthenium-containing compound, of about 93%, even by use of the most favorable adsorbent, and such a rate of recovery cannot be said to be satisfactory in terms of the rate of recovery of a toxic RuO₄ gas.

### Means For Solving the Problems

The present inventors have made intensive studies to solve the above-mentioned problems. Further, the inventors have found that by reducing a ruthenium-containing compound included in a ruthenium-containing liquid or by decreasing the oxidation-reduction potential (ORP) of a ruthenium-containing liquid, it is possible to inhibit the generation of a RuO₄ gas from the ruthenium-containing liquid, thereby completing the present invention.

Specifically, the present invention is configured as follows.

Aspect 1 A method for inhibiting the generation of a RuO₄ gas, comprising a step of adding an inhibitor for inhibiting the generation of a RuO₄ gas, to a ruthenium-containing liquid.

Aspect 2 The method according to Aspect 1, wherein the inhibitor for inhibiting the generation of a RuO₄ gas is added to thereby reduce a ruthenium-containing compound in the ruthenium-containing liquid.

Aspect 3 The method according to Aspect 1, wherein the inhibitor for inhibiting the generation of a RuO₄ gas is added to thereby decrease an oxidation-reduction potential of the ruthenium-containing liquid.

Aspect 4 The method according to any one of Aspects 1 to 3, wherein the inhibitor for inhibiting the generation of a RuO₄ gas is a reducing agent.

Aspect 5 The method according to Aspect 1 or 3, wherein the inhibitor for inhibiting the generation of a RuO₄ gas is a basic compound.

Aspect 6 The method according to Aspect 5, wherein a pH of a ruthenium-containing liquid comprising the basic compound is 12 or more.

Aspect 7 The method according to Aspect 5 or 6, wherein the basic compound is sodium hydroxide, potassium hydroxide, tetraalkylammonium hydroxide, choline, or ammonia.

Aspect 8 The method according to Aspect 4, wherein the reducing agent is hydrogen peroxide or a sulfate compound.

Aspect 9 The method according to Aspect 8, wherein the sulfate compound is sodium thiosulfate or sodium sulfite.

Aspect 10 The method according to any one of Aspects 1 to 9, wherein an oxidation-reduction potential of the ruthenium-containing liquid to which the inhibitor is added is 600 mV or less.

Aspect 11 The method according to any one of Aspects 4 and 8 to 10, wherein an amount of the reducing agent added to the ruthenium-containing liquid is 0.1 molar equivalents or more and 100 molar equivalents or less relative to an objective substance to be reduced.

Aspect 12 An inhibitor for inhibiting the generation of a RuO₄ gas, comprising at least one of a reducing agent and a basic compound.

Aspect 13 The inhibitor for inhibiting the generation of a RuO₄ gas according to Aspect 12, wherein the reducing agent is hydrogen peroxide, sodium thiosulfate, or sodium sulfite.

Aspect 14 The inhibitor for inhibiting the generation of a RuO₄ gas according to Aspect 12, wherein the basic compound is sodium hydroxide, potassium hydroxide, tetraalkylammonium hydroxide, choline, or ammonia.

### Effect of the Invention

According to the method of the present invention, it is possible to continuously inhibit the generation of a RuO₄ gas which is a strong oxidant and which is toxic, from a ruthenium-containing liquid, by using the inhibitor for inhibiting the generation of a RuO₄ gas according to the present invention to thereby reduce a ruthenium-containing compound included in the ruthenium-containing liquid or decrease the oxidation-reduction potential (ORP) of the ruthenium-containing liquid.

### MODE FOR CARRYING OUT THE INVENTION

(Ruthenium-Containing Compound and Ruthenium-Containing Liquid)

The ruthenium-containing compound in the present invention is chemical species containing a ruthenium element, and examples include ruthenium oxides such as RuO₂, RuO₄⁻, or RuO₄²⁻ and a RuO₄ gas, generated in dissolution of metallic ruthenium, and RuO₄ (hereinafter, also referred to as “RuO₄ (aq)”) dissolved in a solution, compounds of ruthenium and halogen, such as RuCl₃, RuBr₃ and RuI₃, and Ru complexes such as Ru(NO₃)₃ and Ru(NO)(NO₃)₃, but, of course, not limited thereto. A liquid comprising even a small amount of the ruthenium-containing compound is referred to as “ruthenium-containing liquid”. Examples of the ruthenium-containing liquid include a liquid discharged in a treatment of ruthenium in an etching step, a residual removal step, a washing step, a CMP step, and the like in a semiconductor production process. Examples also include a liquid generated in washing of ruthenium adhering to chamber inner walls, pipes and the like in each apparatus used in the semiconductor production process. If even a trace amount of the ruthenium-containing compound is included in the ruthenium-containing liquid, RuO₂ particles are generated via a RuO₄ gas and thus cause fouling of tanks and pipes and promote deterioration of apparatuses due to the oxidative effect of the RuO₂ particles. Moreover, a RuO₄ gas generated from the ruthenium-containing liquid exhibits a high toxicity for human body even at a low concentration. The ruthenium-containing liquid thus has various adverse effects on apparatuses or human body, and thus is needed to be treated as soon as possible to thereby allow the generation of a RuO₄ gas to be inhibited.

(Inhibitor For Inhibiting Generation of RuO₄ Gas)

The inhibitor for inhibiting the generation of a RuO₄ gas in the present invention is an inhibitor for inhibiting the generation of a RuO₄ gas (hereinafter, simply referred to as “inhibitor”) which is to be added to the ruthenium-containing liquid in order to inhibit the generation of a RuO₄ gas, and specifically refers to an agent comprising a reducing agent and/or a basic compound, as described below.

(Reducing Agent)

In the present invention, an inhibitor containing a reducing agent can be added to the ruthenium-containing liquid to thereby inhibit the generation of a RuO₄ gas. The reducing agent contained in the inhibitor leads to reduction of the ruthenium-containing compound in the ruthenium-containing liquid or a decrease in ORP of the liquid, to thereby allow the generation of a RuO₄ gas to be inhibited.

That is, the ruthenium-containing compound, which is produced by dissolution of metallic ruthenium, RuO₂, or the like, can be reduced and thus changed to chemical species hardly changed to a RuO₄ gas. The ease of change of ruthenium and the ruthenium-containing compound into a RuO₄ gas can be represented as follows: RuO₄(aq), RuO₄⁻, or RuO₄²⁻, RuO₂ and Ru which are converted into a RuO₄ gas easily in the listed order. That is, RuO₄ (aq) is most easily converted into a RuO₄ gas and Ru is most hardly converted into a RuO₄ gas. Accordingly, any reducing agent which allows the ruthenium-containing compound to be changed to chemical species more hardly gasified has a high effect of inhibiting the generation of a RuO₄ gas. For example, any reducing agent which can allow the ruthenium-containing compound to be changed into Ru, RuO₂, or the like can allow the generation of a RuO₄ gas to be efficiently inhibited and thus can be suitably used as the reducing agent in the present invention. The effect of inhibiting the generation of a RuO₄ gas by the reducing agent is, of course, not limited to the above example, and the generation of a RuO₄ gas is decreased if chemical species more hardly gasified is produced by the reducing agent. For example, in cases where RuO₄⁻ is changed into RuO₄²⁻ or RuO₄ (aq) is changed into RuO₄⁻, by the reducing agent, the ruthenium-containing compound is converted into chemical species more hardly gasified and thus the effect of inhibiting the generation of a RuO₄ gas is obtained. In cases where the reducibility of the reducing agent is high, not only the effect of inhibiting the generation of a RuO₄ gas can be improved, but also reduction to Ru or RuO₂ is made possible. A solid ruthenium-containing compound such as Ru or RuO₂ can be recovered by filtration, evaporation to dryness, or the like. Since ruthenium is a noble metal and expensive, recovery of ruthenium is highly advantageous. Accordingly, the reducing agent to be added to the ruthenium-containing liquid preferably has high reducibility. The reducing agent can be selected in consideration of the reducing ability of the reducing agent to be added, for the purpose of reduction to chemical species dissolved and present in the ruthenium-containing liquid, for example, RuO₄(aq), RuO₄⁻, or RuO₄²⁻ without any precipitation of solid ruthenium. Such reduction of the ruthenium-containing compound to chemical species dissolved and present in the ruthenium-containing liquid can allow the generation of a RuO₄ gas to be inhibited with prevention of clogging of pipes and the like.

(Oxidizing Agent)

The ruthenium-containing liquid is generated in the semiconductor production process, for example, steps of treating ruthenium, such as an etching step, a residual removal step, a washing step, and a CMP step, as described above, and thus the liquid often includes an oxidizing agent for dissolving ruthenium. Examples of the oxidizing agent can include halogen oxyacid, permanganic acid, and any salt thereof, hydrogen peroxide, ozone, and a cerium (IV) salt, but not limited thereto. In particular, examples of an oxidizing agent possibly included in the ruthenium-containing liquid include halogen oxyacid and ion thereof, or hydrogen peroxide, because such an agent is stably used in an alkaline environment where a RuO₄ gas is hardly generated and a wide concentration range can be selected. The halogen oxyacid here refers to hypochlorous acid, chlorous acid, chloric acid, perchloric acid, hypobromous acid, bromous acid, bromic acid, perbromic acid, hypoiodous acid, iodous acid, iodic acid, metaperiodic acid, orthoperiodic acid, or any ion thereof. In the present invention, the reducing agent is added to the ruthenium-containing liquid to thereby reduce such an oxidizing agent and decrease the oxidation-reduction potential (ORP) of the liquid, thereby allowing the generation of a RuO₄ gas to be inhibited.

(Oxidation-Reduction Potential of Ruthenium-Containing Liquid)

The ORP of the ruthenium-containing liquid is determined by, for example, the type and the concentration of the ruthenium-containing compound included in the liquid, the type and the concentration of the reducing agent included in the liquid, and the types and the concentrations of the oxidizing agent and other additives which can be contained in the liquid. In general, as a larger amount of an oxidizing agent is contained in a solution and the oxidizing agent has a stronger oxidative power, the ORP of the solution is increased. On the contrary, as a larger amount of a reducing agent is added to a solution and the reducing agent has a stronger reductive power, the ORP of the solution is decreased. RuO₄(aq), RuO₄⁻, RuO₄²⁻, RuO₂, and the like which are each a ruthenium-containing compound are each an oxidizing agent having a strong oxidative power, and thus the ORP of the ruthenium-containing liquid often exhibits a relatively high value.

The amount of the generation of a RuO₄ gas depends on the ORP of the ruthenium-containing liquid, and a higher ORP leads to a larger amount of the generation of a RuO₄ gas. On the contrary, a lower ORP of the ruthenium-containing liquid allows the ruthenium-containing compound to be more easily present stably in the form of a chemical form hardly gasified, and thus the amount of the generation of a RuO₄ gas is decreased. For example, any ORP at which RuO₂ or Ru as chemical species relatively hardly converted into a RuO₄ gas is stably present is often lower by about 100 to 500 mV than any ORP at which RuO₄ (aq), RuO₄⁻, or the like as chemical species easily converted into a RuO₄ gas is stably present, depending on conditions. It is thus effective for inhibiting the generation of a RuO₄ gas in the ruthenium-containing liquid to decrease the ORP of the ruthenium-containing liquid.

Furthermore, when the ORP of the ruthenium-containing liquid is decreased, a reaction for generating chemical species easily converted into a RuO₄ gas, for example, a reaction for oxidizing RuO₄⁻ to RuO₄ (aq) hardly progresses, and thus the generation of a RuO₄ gas is inhibited. Furthermore, in cases where a reduction reaction of the ruthenium-containing compound occurs by decreasing the ORP of the ruthenium-containing liquid, the ruthenium-containing compound is changed into chemical species which is more hardly converted into a RuO₄ gas than that before the reaction. For example, in cases where RuO₄⁻ is reduced, reduction to RuO₄²⁻, RuO₂, or Ru by the reduction reaction can decrease the amount of the generation of a RuO₄ gas.

Even in cases where a decrease in ORP of the ruthenium-containing liquid, occurring by addition of the reducing agent, is small and no reduction reaction of the ruthenium-containing compound occurs, such a decrease in ORP can allow the ruthenium-containing compound to be more stably present in the ruthenium-containing liquid. The reason for this is because such a decrease in ORP hardly causes the change of the ruthenium-containing compound into a RuO₄ gas. Accordingly, only such a decrease in ORP can allow the generation of a RuO₄ gas to be inhibited even by no occurrence of the change in chemical form of ruthenium.

For the reason, the ORP of the liquid is preferably 600 mV or less, more preferably 450 mV or less, still more preferably 300 mV or less, regardless of the pH, in cases where the reducing agent is added to the ruthenium-containing liquid. An ORP of less than 600 mV allows RuO₄⁻ to be extremely hardly present, to result in a significant increase in proportion of RuO₄²⁻ present, thereby hardly causing the generation of a RuO₄ gas. The ORP is a value relative to that of a standard hydrogen electrode at 25° C.

For example, a method for reducing an oxidizing agent contained in the ruthenium-containing liquid is considered to be adopted for a decrease in ORP of the liquid. The ruthenium-containing liquid is generated in dissolution of metallic ruthenium, RuO₂, or the like in the semiconductor production process, and thus the liquid often includes an oxidizing agent. If the oxidizing agent is present, the ORP of the liquid is higher and thus a RuO₄ gas is easily generated. If the reducing agent is added to the ruthenium-containing liquid, the oxidizing agent can be reduced to thereby decrease the ORP of the liquid and inhibit the generation of a RuO₄ gas. Furthermore, the ORP of the ruthenium-containing liquid can also be decreased by reducing other chemical species included in the ruthenium-containing liquid, for example, a solvent molecule, metal species other than ruthenium, and any component contained in a treatment liquid for a semiconductor. Of course, the ORP of the ruthenium-containing liquid can be decreased and the generation of a RuO₄ gas can be inhibited also by reducing the ruthenium-containing compound, for example, RuO₄(aq), RuO₄⁻, RuO₄²⁻, or RuO₂ with the reducing agent added to the ruthenium-containing liquid.

Furthermore, another method for decreasing the ORP of the ruthenium-containing liquid is a method for adding a basic compound to the liquid. In cases where H′ or OH⁻ is included in a half reaction of oxidation-reduction species for determining the ORP of the liquid, namely, H⁺ or OH⁻ involves in an oxidation-reduction reaction between an oxidant and a reductant of the oxidation-reduction species, a higher pH leads to a more decrease in ORP of the oxidation-reduction species at the pH. Therefore, the oxidation-reduction potential (ORP) of the ruthenium-containing liquid is also decreased according to an increase in pH of the liquid, and thus the generation of RuO₄ hardly occurs. A basic compound described below can be used in order that the ORP of the ruthenium-containing liquid is decreased by a basic compound included in the inhibitor according to the present invention.

For the reason, the reducing agent which can be contained in the inhibitor according to the present invention can be any substance which can reduce the oxidizing agent contained in the ruthenium-containing compound and/or the ruthenium-containing liquid. Examples include sulfate compounds (including thiosulfate, sulfite, pyrosulfite, and sulfate) such as sodium thiosulfate, sodium sulfite, ammonium sulfite, iron sulfite, sodium hyposulfite, sodium hydrogen sulfite, potassium sulfite, and sodium pyrosulfite, hydrogen peroxide, alcohol compounds typified by 2-propanol, hydrocarbon-based polymer compounds such as polyethylene glycol and polypropylene glycol, carbonyl compounds such as oxalic acid, formic acid, gallic acid, ascorbic acid, and tocopherol, metal-containing compounds such as iron (II) ion, tin (II) ion, lithium aluminum hydride, boron sodium hydride, diisobutylaluminum hydride, sodium amalgam, and zinc amalgam, amine compounds typified by hydroxylamine, phenol compounds typified by hydroquinone, aldehyde compounds, and hydrazine. In particular, a sulfate compound and hydrogen peroxide are preferable, and sodium thiosulfate, sodium sulfite, and hydrogen peroxide are still more preferable, from the viewpoint of the degree of reducibility and cost. Such a reducing agent can be used singly or in combination of a plurality thereof.

The reducing agent is added in order to reduce the ruthenium-containing compound and/or the oxidizing agent (hereinafter, referred to as “ruthenium-containing compound and/or the like, or objective substance to be reduced”) and/or decrease the ORP of the ruthenium-containing liquid, as described above. The reducing agent added, even if in a small amount, rapidly reacts with the ruthenium-containing compound and the like, or rapidly decreases the ORP of the ruthenium-containing liquid and exerts the effect of inhibiting the generation of a RuO₄ gas. A larger amount of the reducing agent added leads to an increase in effect of inhibiting the generation of a RuO₄ gas, and thus such an amount is preferably larger than the amount which enables all of the ruthenium-containing compound and the like to be reduced. The ratio of the amount of the reducing agent added, to the amount of the ruthenium-containing compound and the like present depends on the types of the oxidizing agent and the reducing agent. For example, in cases where hypochlorous acid is reduced using hydrogen peroxide or sodium sulfite, the molar ratio in such a reaction is as follows, oxidizing agent: reducing agent=1:1. On the other hand, in cases where the oxidizing agent is reduced by sodium thiosulfate, the molar ratio in such a reaction is 4:1, and thus a smaller amount of sodium thiosulfate can reduce the same amount of the oxidizing agent. The number of moles of the reducing agent necessary for reduction of all of the ruthenium-containing compound and the like in the ruthenium-containing liquid, described above, is defined as 1 molar equivalent. That is, while hydrogen peroxide and sodium thiosulfate are different in number of moles necessary for reduction of the same amount of hypochlorous acid, as described above, the amount necessary for reduction of the entire oxidizing agent in the ruthenium-containing liquid is 1 molar equivalent even in each case of such reducing agents.

While the amount of the reducing agent added is preferably larger than the amount which enables all of the ruthenium-containing compound and the like to be reduced, as described above, a small amount thereof can also be used without any problems as long as the effect of inhibiting the generation of a RuO₄ gas is exerted. That is, the amount of the generation of a RuO₄ gas can be decreased by partially reducing the ruthenium-containing compound or the oxidizing agent to thereby provide ruthenium chemical species hardly converted into a RuO₄ gas, as described above, or decreasing the ORP of the ruthenium-containing liquid.

For the reason, the amount of the reducing agent added to the ruthenium-containing liquid is preferably 0.1 molar equivalents or more and 100 molar equivalents or less, still more preferably 0.2 molar equivalents or more and 50 molar equivalents or less, most preferably 1 molar equivalent or more and 10 molar equivalents or less, relative to the objective substance to be reduced, for example, the ruthenium-containing compound.

The concentration of the reducing agent in the inhibitor is not particularly limited, and can be, for example, 0.0001 mol/L or more and 10.0 mol/L or less and is preferably 0.1 mol/L or more and 8 mol/L or less, more preferably 1 mol/L or more and 5 mol/L or less. Only the reducing agent can be used in the inhibitor.

The purity of the reducing agent is not limited as long as the effect of inhibiting the generation of a RuO₄ gas is exerted. A case where the purity of the reducing agent has any influence on the effect of inhibiting the generation of a RuO₄ gas is considered to be a case where a RuO₄ gas is generated by a reaction of impurities or degraded products of impurities included in the reducing agent, with the ruthenium-containing compound. A case where such impurities or degraded products of impurities are each a substance causing a decrease in pH of the ruthenium-containing liquid is not preferable because a RuO₄ gas is generated according to the above principle. Accordingly, the reducing agent is preferably high in purity, while impurities can be contained as long as these do not promote the generation of a RuO₄ gas.

The form of the reducing agent can be in any form of solid, liquid, and gas as long as the effect of inhibiting the generation of a RuO₄ gas is exerted. A solid, liquid, or gas including the reducing agent can also be adopted. An appropriate form can be selected in consideration of cost, workability, facilities, and the like in a step of reducing the ruthenium-containing compound. For example, when the reducing agent in the form of a solid and an aqueous solution of the reducing agent are compared, such a solid reducing agent can be used to thereby suppress the treatment cost of a waste liquid because the amount of the waste liquid is small. On the other hand, the aqueous solution of the reducing agent is used to thereby impart favorable operation ability, and easy stirring and mixing with the ruthenium-containing liquid, and allow the effect of inhibiting the generation of a RuO₄ gas to be rapidly exerted, as compared with the solid reducing agent. The reducing agent in the form of a gas, although needs facilities such as pipes and is costly, can be used in the case for example, the generation of a reducible gas as a waste product in a manufacturing site of a semiconductor. Examples of such a gaseous reducing agent include hydrogen, phosphine, nitrogen dioxide, hydrogen sulfide, and sulfur dioxide.

(Basic Compound)

An inhibitor containing a basic compound can be added to the ruthenium-containing liquid to thereby inhibit the generation of a RuO₄ gas. The basic compound is added to result in an increase in pH of the ruthenium-containing liquid and a decrease in ORP. Thus, the ruthenium-containing compound is changed into chemical species hardly gasified or is stably present as the same chemical species, according to the above principle, and thus the generation of a RuO₄ gas can be inhibited.

If the pH of the ruthenium-containing liquid is more than 12, the proportion of RuO₄⁻ present is decreased and the proportion of RuO₄²⁻ present is significantly increased, and thus a RuO₄ gas is hardly generated. Accordingly, the pH of the liquid to which the basic compound is added is preferably 12 or more, more preferably 13 or more, still more preferably 14 or more. In this regard, the upper limit of the pH is not particularly limited, and is usually 15 or less. The amount of the basic compound added to the ruthenium-containing liquid is not particularly limited, and is preferably set so that the pH of the ruthenium-containing liquid to which the basic compound is added is in the above-mentioned range. In this regard, a pH refers to the value at 25° C. in this specification.

The basic compound can be any compound as long as it can increase the pH of the ruthenium-containing liquid, and is not particularly limited, and examples thereof include tetraalkylammonium hydroxide, sodium hydroxide, potassium hydroxide, calcium hydroxide, magnesium hydroxide, an amine compound, ammonia, and choline. In particular, tetramethylammonium hydroxide can be suitably used as the tetraalkylammonium hydroxide in terms of cost and availability because of being generally used in the semiconductor production process. Such a basic compound can be used singly or in combination of a plurality thereof.

The purity and the form of the basic compound are not limited from the same reason as in the case of the reducing agent as long as the effect of inhibiting the generation of a RuO₄ gas is exerted.

The concentration of the basic compound in the inhibitor is not particularly limited, can be, for example, 0.01 mol/L or more and 15 mol/L or less, and is preferably 0.1 mol/L or more and 5 mol/L or less, more preferably 1 mol/L or more and 3 mol/L or less. Only the basic compound can be used in the inhibitor.

Even in cases where both the reducing agent and the basic compound are used in the inhibitor, the respective concentration ranges thereof in the inhibitor can be the above-mentioned ranges.

The basic compound can be used concurrently with the above-mentioned reducing agent. The basic compound and the reducing agent can be used concurrently to not only reduce the ruthenium-containing compound, but also further decrease the ORP. Thus, the generation of a RuO₄ gas can be more inhibited.

The temperature at which the inhibitor according to the present invention is used is not particularly limited, and can be appropriately selected in consideration of the temperature of the ruthenium-containing liquid to which the inhibitor is to be added, the location of use, the season, the cost, the effect of inhibiting the generation of a RuO₄ gas, and the like. In cases where the inhibitor in the form of a liquid or a liquid including the inhibitor is used, any temperature range causing neither freezing nor boiling (evaporating) can be adopted. A high temperature of the ruthenium-containing liquid tends to easily cause the generation of a RuO₄ gas and thus the temperature in use is preferably −35° C. to 80° C., more preferably −10° C. to 60° C., still more preferably 0° C. to 50° C.

(Other Additives)

The inhibitor according to the present invention can optionally include any of other additives which have been conventionally used in a treatment liquid for a semiconductor as long as the object of the present invention is not impaired. For example, an acid, a metal anticorrosive agent, an organic solvent, a fluorine compound, a complexing agent, a chelating agent, a surfactant, an antifoaming agent, a pH adjuster, a stabilizer, a dispersant, and/or metal ion can be used as such other additive(s). Such additives can be added singly or in combination of a plurality thereof.

Examples of the balance excluding at least one of the reducing agent and the basic compound, and optional additive(s) described above, in the inhibitor, can include a solvent, and examples can include water, acetonitrile, and sulfolane. Only the reducing agent or the basic compound can be used singly or a mixture of the reducing agent and the basic compound can be used singly, in the inhibitor.

(Method for Inhibiting Generation of RuO₄ Gas)

The method for inhibiting the generation of a RuO₄ gas according to the present invention is a method for treating the ruthenium-containing liquid, the method including a step of adding the above inhibitor to the above ruthenium-containing liquid. According to the method, a RuO₄ gas generated from the ruthenium-containing liquid can be inhibited according to the above-mentioned mechanism. Thus, not only handling of the ruthenium-containing liquid is facilitated, but also exhaust equipment and removal equipment can be simplified, and the cost required for the treatment of a RuO₄ gas can be reduced. Furthermore, the risk of operators being exposed to a highly toxic RuO₄ gas is reduced, and safety is significantly improved.

Examples of a general method for using the present invention include a method involving adding the above inhibitor to the ruthenium-containing liquid generated in the semiconductor production process or the like. In this case, the method for adding the inhibitor to the ruthenium-containing liquid is not particularly limited, and, for example, a tank to which the inhibitor is added in advance can be used as a waste liquid tank in the semiconductor production process to thereby prevent the generation of a RuO₄ gas from the ruthenium-containing liquid. The waste liquid tank receives the inhibitor in advance, and thus the ruthenium-containing compound generated is instantly reduced and any concern about the generation of a RuO₄ gas is eliminated. A method involving adding the inhibitor according to the present invention to a ruthenium-containing liquid generated by treating a wafer containing ruthenium is also one of desirable aspects of the present invention. The inhibitor can be added immediately after the generation of the ruthenium-containing liquid to thereby minimum the generation of a RuO₄ gas. In this case, addition of the inhibitor is preferably performed in a semiconductor production apparatus or any of pipes in the vicinity of the apparatus.

The inhibitor according to the present invention can be used to thereby inhibit the generation of a RuO₄ gas even in washing of ruthenium adhering to chamber inner walls, pipes and the like of the respective apparatuses used in the semiconductor production process. For example, the inhibitor according to the present invention can be added to a ruthenium-containing liquid generated in removal of ruthenium adhering to chambers, tools, pipes and the like in the maintenance of an apparatus for forming Ru by use of, for example, a physical vapor deposition (PVD), chemical vapor deposition (CVD), or atomic layer deposition (ALD) method, or an apparatus for washing a ruthenium-containing wafer, to thereby inhibit a RuO₄ gas. According to the method, a RuO₄ gas can be efficiently inhibited from being generated according to the above-mentioned mechanism.

The ruthenium-containing liquid has various adverse effects on apparatuses or human body, and thus is needed to be treated safely and rapidly with the generation of a RuO₄ gas being inhibited. The inhibitor according to the present invention can be added to the ruthenium-containing liquid to thereby inhibit the generation of a RuO₄ gas, and not only allow the ruthenium-containing liquid to be safely treated, but also allow contamination and/or degradation of the tank and pipes of an apparatus to be relieved.

The concentration of the inhibitor, the pH, the treatment temperature, and other conditions in the method for inhibiting the generation of a RuO₄ gas of the present invention, here adopted, can be suitably the above-mentioned values.

### EXAMPLES

Hereinafter, the present invention will be more specifically described with reference to Examples, but the present invention is not limited to these Examples.

### Example 1

(Preparation of Ruthenium-Containing Liquid)

After 52 g of 39% sodium hypochlorite (manufactured by Junsei Chemical Co., Ltd.), 8 g of 97% tetramethylammonium bromide (manufactured by Tokyo Chemical Industry Co., Ltd.), and 940 g of ultrapure water were added into a fluororesin container, the pH was adjusted to 12.0 by use of an aqueous 4 weight % NaOH solution, to thereby obtain a treatment liquid for Ru etching. A 300-mm Si wafer on which a ruthenium film having a thickness of 2720 Å was formed was immersed in 1 L of the liquid obtained, at 25° C. for 10 minutes, and the ruthenium-containing liquid produced was recovered in a waste liquid tank.

(Mixing of Ruthenium-Containing Liquid and Reducing Agent)

23 g of 95% sodium thiosulfate (manufactured by FUJIFILM Wako Pure Chemical Corporation) was taken in a fluororesin container and dissolved in ultrapure water, to thereby obtain an aqueous saturated sodium thiosulfate solution (solution containing an inhibitor). Seventy-five mL of the aqueous saturated sodium thiosulfate solution was added into the waste liquid tank receiving 1 L of the ruthenium-containing liquid, and mixed with the ruthenium-containing liquid, to thereby obtain a mixed liquid of the ruthenium-containing liquid and the inhibitor.

(Ru Analysis in Mixed Liquid)

Ru in the mixed liquid obtained was subjected to quantitative analysis with ICP-OES and qualitative analysis with an ultraviolet visible spectrophotometer (UV-2600, manufactured by SHIMADZU CORPORATION) for respective periods described in Table 2. The day of preparation of the mixed liquid was designated as day 0 in Table 2, and the respective amounts of Ru in the liquid at days 1, 2, 3, 10, 20, and 30 were measured under the assumption that the amount of Ru in the liquid at day 0 was 1.00. The mixed liquid was airtightly stored in a polypropylene bottle at times other than such each analysis so that a RuO₄ gas was not volatilized out of the system.

### Examples 2 to 10

Each mixed liquid of the ruthenium-containing liquid and the inhibitor was prepared so as to have each composition described in Table 1 and the mixed liquid was subjected to Ru analysis, according to the same procedure as in Example 1. In Examples 5 and 6, a 30% hydrogen peroxide solution was used and thus no dilution with ultrapure water was performed. In Examples 7 and 8, a basic compound (25% tetramethylammonium hydroxide) was used as the inhibitor, and no dilution with ultrapure water was again performed.

### Example 11

A mixed liquid of the ruthenium-containing liquid and the inhibitor was prepared so as to have a composition described in Table 1 and the mixed liquid was subjected to Ru analysis, according to the same procedure as in Example 1. Herein, the reducing agent was not an aqueous saturated solution mixed with ultrapure water, and powdery sodium thiosulfate was directly added to the ruthenium-containing liquid. The molar equivalent shown in Table I was a molar equivalent relative to the total of the ruthenium-containing compound and the oxidizing agent.

### Example 12

The same procedure as in Example 1 was performed except that the reducing agent was placed in the waste liquid tank in advance before recovery of the ruthenium-containing liquid in the waste liquid tank.

### Comparative Example 1

A ruthenium-containing liquid was obtained by the same method as in Example 1. Herein, no inhibitor was added to the ruthenium-containing liquid. Ru in the ruthenium-containing liquid obtained was analyzed.

TABLE 1

| | Ruthenium-containing liquid | | | Inhibitor | | | Mixed liquid | | | |
|---|---|---|---|---|---|---|---|---|---|---|
| | Concentration | Oxidizing | | Reducing | Basic | | | ORP | Molar | Reduced |
| | of Ru | agent | pH | agent | compound | pH | pH | (mVvs. SHE) | equivalent | or not |
| Example 1 | 2.4 × | 0.28 mol | 12 | 0.14 mol | — | — | 1.5 | — | 0.5 | Reduced |
| | 10⁻³ mol/L | | | Na₂S₂O₃ | | | | | | |
| Example 2 | | | | 0.07 mol | — | — | 1.5 | 410 | 1 | Reduced |
| | | | | Na₂S₂O₃ | | | | | | |
| Example 3 | | | | 0.28 mol | — | — | 12 | 220 | 1 | Reduced |
| | | | | Na₂SO₃ | | | | | | |
| Example 4 | | | | 0.035 mol | — | — | 12 | — | 0.125 | — |
| | | | | Na₂SO₃ | | | | | | |
| Example 5 | | | | 0.28 mol | — | — | 12 | 270 | 1 | Reduced |
| | | | | H₂O₂ | | | | | | |
| Example 6 | | | | 0.035 mol | — | — | 12 | — | 0.125 | — |
| | | | | H₂O₂ | | | | | | |
| Example 7 | | | | — | 1.6 mol | 14.4 | 14 | 170 | — | Reduced |
| | | | | | TMAH | | | | | |
| Example 8 | | | | — | 7.3 mol | 14.4 | 14.3 | 140 | — | Reduced |
| | | | | | TMAH | | | | | |
| Example 9 | | | | 0.07 mol | 0.16 mol | 14.1 | 12.6 | 170 | 1 | Reduced |
| | | | | Na₂S₂O₃ | TMAH | | | | | |
| Example 10 | | | | 0.008 mol | 0.025 mol | 14.2 | 12.1 | — | 0.11 | — |
| | | | | Na₂S₂O₃ | TMAH | | | | | |
| Example 11 | | | | 0.07 mol | — | — | 1.5 | 400 | 1 | Reduced |
| | | | | Na₂S₂O₃ | | | | | | |
| Example 12 | | | | 0.07 mol | — | — | 1.5 | 405 | 1 | Reduced |
| | | | | Na₂S₂O₃ | | | | | | |
| Comparative | | | | — | — | — | 12 | 750 | — | — |
| Example 1 | | | | | | | | | | |

*TMAH = tetramethylammonium hydroxide, Na₂S₂O₃ = sodium thiosulfate, Na₂SO₃ = sodium sulfite, H₂O₂ = hydrogen peroxide

TABLE 2

| | | Period [days] | | | | | | |
|---|---|---|---|---|---|---|---|---|
| | | 0 | 1 | 2 | 3 | 10 | 20 | 30 |
| Amount | Example 1 | 1.00 | 1.00 | 0.99 | 1.00 | 1.00 | 0.99 | 1.00 |
| of Ru in | Example 2 | 1.00 | 1.00 | 0.97 | 1.00 | 0.98 | 1.00 | 1.00 |
| liquid | Example 3 | 1.00 | 0.97 | 1.00 | 1.00 | 0.98 | 1.00 | 1.00 |
| | Example 4 | 1.00 | 0.55 | — | — | — | — | — |
| | Example 5 | 1.00 | 0.98 | 0.99 | 1.00 | 1.00 | 0.99 | 1.00 |
| | Example 6 | 1.00 | 0.50 | — | — | — | — | — |
| | Example 7 | 1.00 | 0.99 | 0.99 | 0.98 | 0.96 | 0.93 | 0.90 |
| | Example 8 | 1.00 | 1.00 | 1.00 | 0.98 | 1.00 | 1.00 | 0.99 |
| | Example 9 | 1.00 | 1.00 | 0.99 | 1.00 | 1.00 | 0.98 | 1.00 |
| | Example 10 | 1.00 | 0.60 | — | — | — | — | — |
| | Example 11 | 1.00 | 0.98 | 1.00 | 1.00 | 1.00 | 0.99 | 1.00 |
| | Example 12 | 1.00 | 1.00 | 1.00 | 0.99 | 1.00 | 0.99 | 1.00 |
| | Comparative | 1.00 | 0.05 | — | — | 0.01 | — | 0.00 |
| | Example 1 | | | | | | | |

It could be confirmed from the results of Table 2 that the amount of ruthenium in the mixed liquid in Comparative Example 1 was significantly decreased and most of ruthenium was dissipated in the form of a RuO₄ gas from the mixed liquid.

It could be confirmed that Examples 1 to 6 in which the inhibitor was added to the ruthenium-containing liquid each enabled the generation of a RuO₄ gas from the mixed liquid to be inhibited as compared with Comparative Example 1.

It could be confirmed that Examples 7 and 8 in which the basic compound was added to the ruthenium-containing liquid each exhibited a significantly decreased ORP and enabled the generation of a RuO₄ gas from the mixed liquid to be inhibited as compared with Comparative Example 1.

It was found that Example 9 in which the basic compound was further added as compared with Example 2 in which only the reducing agent was added exhibited a decreased ORP and also exerted a high effect of inhibiting the generation of a RuO₄ gas, as compared with Example 2.

It could be confirmed that Example 11 in which the powdery reducing agent was added to the ruthenium-containing liquid enabled the volatilization of a RuO₄ gas to be inhibited as well as Example 2 in which an aqueous solution of the reducing agent was added.

It could be confirmed by an ultraviolet visible spectrophotometric spectrum that RuO₄⁻ present in the ruthenium-containing liquid in each of Examples 1 to 3, 5, 7 to 9, 11, and 12 was reduced to RuO₂ or RuO₄²⁻ due to addition of the inhibitor.

From the above results, the method according to the present invention can be suitably used as a method for inhibiting the generation of a RuO₄ gas from a ruthenium-containing liquid.

1. A method for inhibiting the generation of a RuO₄ gas, comprising a step of adding an inhibitor for inhibiting the generation of a RuO₄ gas, to a ruthenium-containing liquid.

2. The method according to claim 1, wherein the inhibitor is added to thereby reduce a ruthenium-containing compound in the ruthenium-containing liquid.

3. The method according to claim 1, wherein the inhibitor is added to thereby decrease an oxidation-reduction potential of the ruthenium-containing liquid.

4. The method according to claim 1, wherein the inhibitor for inhibiting the generation of a RuO₄ gas is a reducing agent.

5. The method according to claim 1, wherein the inhibitor for inhibiting the generation of a RuO₄ gas is a basic compound.

6. The method according to claim 5, wherein a pH of a ruthenium-containing liquid comprising the basic compound is 12 or more.

7. The method according to claim 5, wherein the basic compound is sodium hydroxide, potassium hydroxide, tetraalkylammonium hydroxide, choline, or ammonia.

8. The method according to claim 4, wherein the reducing agent is hydrogen peroxide or a sulfate compound.

9. The method according to claim 8, wherein the sulfate compound is sodium thiosulfate or sodium sulfite.

10. The method according to claim 1, wherein an oxidation-reduction potential of the ruthenium-containing liquid to which the inhibitor is added is 600 mV or less.

11. The method according to claim 4, wherein an amount of the reducing agent added to the ruthenium-containing liquid is 0.1 molar equivalents or more and 100 molar equivalents or less relative to an objective substance to be reduced.

12. An inhibitor for inhibiting the generation of a RuO₄ gas, comprising at least one of a reducing agent and a basic compound.

13. The inhibitor for inhibiting the generation of a RuO₄ gas according to claim 12, wherein the reducing agent is hydrogen peroxide, sodium thiosulfate, or sodium sulfite.

14. The inhibitor for inhibiting the generation of a RuO₄ gas according to claim 12, wherein the basic compound is sodium hydroxide, potassium hydroxide, tetraalkylammonium hydroxide, choline, or ammonia.
